(19) United States
(12) Patent Application Publication
(10) Pub. No.: US 2013/0043055 A1
(43) Pub. Date: Feb. 21, 2013

(54) Junction Box

(71) Applicants: Qingtai Ma, Shanghai (CN); Xiaoqun Chen, Shanghai (CN); Zhenhua Zhang, Shanghai (CN); Feng Wang, Shanghai (CN)

(72) Inventors: Qingtai Ma, Shanghai (CN); Xiaoqun Chen, Shanghai (CN); Zhenhua Zhang, Shanghai (CN); Feng Wang, Shanghai (CN)

(21) Appl. No.: 13/586,286

(22) Filed: Aug. 15, 2012

(30) Foreign Application Priority Data
Aug. 15, 2011 (CN) 201120295562.5

(51) Int. Cl. H02G 3/18; H05K 5/06; H01R 13/46

(52) U.S. Cl. 174/50.54; 174/520; 174/59

(57) ABSTRACT

A junction box for a photovoltaic module is provided. The junction includes a housing and a base. The housing is prepared from a first material. The base is provided in the housing and configured to mount an electronic device. The base is prepared from a second material. With the housing and the base being separated from each other and made of different materials, the junction box meets the design requirements regarding a system voltage range of 600-1,000V according to UL.

### CROSS-REFERENCE TO RELATED APPLICATION

This application claims priority under 35 U.S.C. §119 to Chinese Patent Application No. 201120295562.5 filed on Aug. 15, 2011.

### FIELD OF THE INVENTION

The invention relates to a junction box for connection with a cable and, more particularly, to a junction box for connection with a cable for a solar photovoltaic (PV) module.

### BACKGROUND

In an electronic system, such as a solar photovoltaic module and a communication module, an outer cable is generally used to transmit weak electrical signals into an electronic device provided in a junction box, to collect the weak electrical signals in an external electronic apparatus such as a solar current collector, or to transmit the weak electrical signals to an external electronic apparatus.

Generally, a known junction box includes a connection terminal for electrically connecting with an outer cable, a plurality of bypass diodes, and a connection assembly connected between the connection terminal and the electronic device. Conductive elements, such as the connection terminal, the diodes and the connection assembly are positioned on a base of the junction box, which is formed integrally with a main body of the junction box.

The known junction box may satisfy the design requirements of a system having a voltage range of less than 600V according to Underwriter Laboratories Inc. (UL). However, the known junction box design cannot meet the Incline Plate Checking (IPT) testing requirement, i.e., a product material withstanding capacity of 2.5 KV per hour at a system voltage range of greater than 600V. For instance, under a system voltage of 1,000V, the material used in the known junction box cannot meet the safety requirements of UL.

### SUMMARY

The present invention has been made to overcome or alleviate at least one aspect of the above mentioned disadvantages.

A junction box for a photovoltaic module is provided. The junction includes a housing and a base. The housing is made from a first material. The base is provided in the housing and configured to mount an electronic device. The base is made from a second material. With the housing and the base being separated from each other and made of different materials, the junction box meets the design requirements regarding a system voltage range of 600-1,000V according to UL.

### BRIEF DESCRIPTION OF THE DRAWINGS

These and/or other aspects and advantages of the invention will become apparent and more readily appreciated from the following description of the embodiments, taken in conjunction with the accompanying drawing of which:

FIG. 1 is a perspective view of a junction box according to the invention;

FIG. 2 is a top view of the junction box of FIG. 1;

FIG. 3 is an exploded view of the junction box of FIG. 1;

FIG. 4 is a perspective view of a junction box according to another embodiment of the invention;

FIG. 5 is a top view of the junction box of FIG. 4;

FIG. 6 is an exploded view of the junction box of FIG. 4;

FIG. 7 is a perspective view of a junction box according to another embodiment of the invention;

FIG. 8 is a top view of the junction box of FIG. 7;

FIG. 9 is an exploded view of the junction box of FIG. 7;

FIG. 10 is a perspective view of a junction box according to another embodiment of the invention;

FIG. 11 is a perspective view of the junction box of FIG. 10, wherein a cover is removed from the junction box shown in FIG. 10;

FIG. 12 is a perspective view of the junction box of FIG. 11, wherein no cable is connected to the junction box shown in FIG. 10;

FIG. 13 is a top view of the junction box of FIG. 12;

FIG. 14 is a perspective view of the base and the electronic devices on the base in the junction box of FIG. 11;

FIG. 15 is a perspective view of the junction box of FIG. 12 along the line A-A;

FIG. 16 is a side view of the junction box of FIG. 15;

FIG. 17 is a perspective view of the partial junction box of FIG. 15, wherein the base and the electronic devices are removed;

FIG. 18 is a side view of the junction box of FIG. 17;

FIG. 19 is a perspective view of a junction box according to another embodiment of the invention, wherein the cover is removed;

FIG. 20 is a perspective view of the junction box of FIG. 19, wherein the base and the electronic devices are removed; and

FIG. 21 is a perspective view of the base and the electronic devices on the base in the junction box of FIG. 19.

### DETAILED DESCRIPTION OF THE EMBODIMENT(S)

The embodiments of the invention will be described hereinafter in detail with reference to the attached drawings, wherein the like reference numerals refer to the like elements throughout the specification. These embodiments should not be construed as being limited to the embodiment set forth herein, but rather for illustrative purpose.

The junction box according to exemplary embodiments of the invention may be used to electrically connect an external cable of an electronic system, such as a solar PV module, for transmitting or generating weak electrical signals to an electronic device mounted within the junction box, for further collecting the weak electrical signals in an external electronic apparatus such as a solar current collector, or for transmitting the weak electrical signals to the external electronic apparatus.

The junction box according to exemplary embodiments of the invention may meet the design requirements of a system voltage range of 600-1,000V or higher according to the requirements of UL (Underwriter Laboratories Inc.).

The junction box according to exemplary embodiments of the invention, for example, for a photovoltaic module, includes a housing, and a base provided in the housing and configured to mount at least one electronic device, wherein the housing and the base are separated from each other and are made of different materials. In particular, the material for forming the base has a higher voltage rating than a material used for forming the housing. For instance, the housing is made of thermoplastic material and the base is made of thermosetting material.

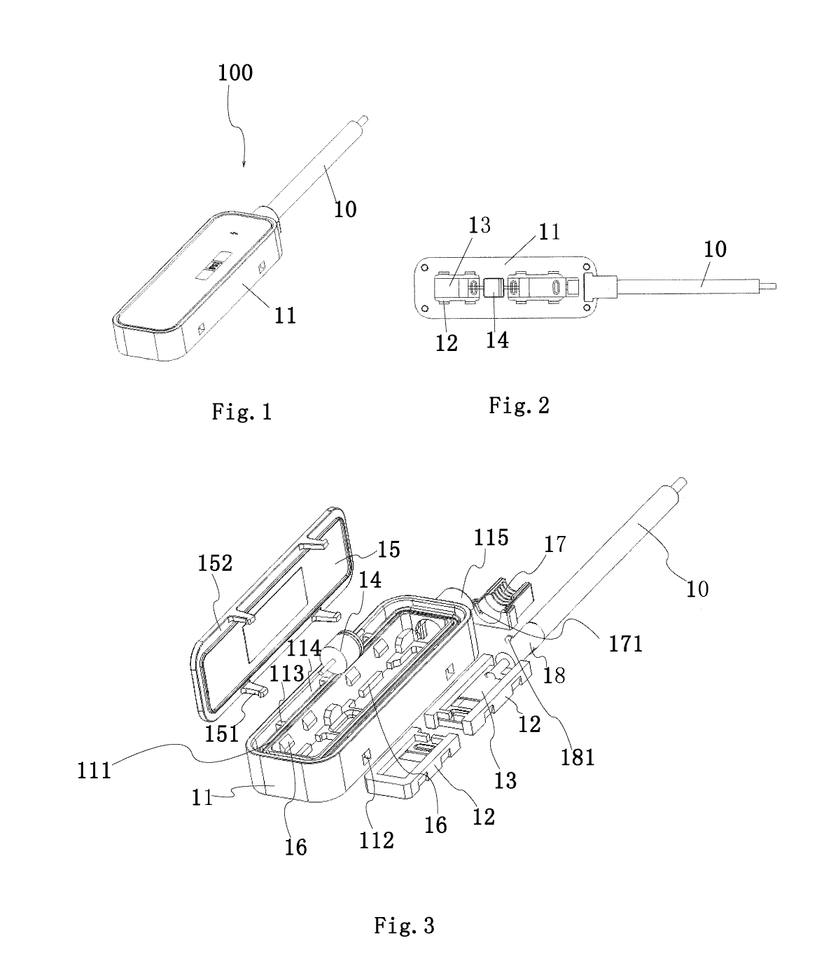

Now with reference to FIGS. 1 through 3, a junction box 100 for a photovoltaic module (not shown) includes a housing 11 and a base 12 provided in the housing 11, wherein at least one electronic device is mounted on the base 12, and the housing 11 and the base 12 are separated from each other and are made of different materials. Further, the material for forming the base 12 has a higher voltage rating than a material used for forming the housing 11. The housing 11 may be made of thermoplastic material, such as PPO or PPE (polyphenyl ether), PA (polyamide), PBT, PVC, PP, PE, polystyrene, polyformaldehyde, crylic acid and the like, while the base 12 is made of thermosetting material, such as BMC (Bulk Molding Compounds), in particular BMC 610 or BMC 620. In another exemplary embodiment, the base 12 may be made of thermosetting material, such as phenolic aldehyde, melamine formaldehyde, unsaturated polyester or organosilicon.

Because the thermosetting material is heat-resistant, insulating and has a higher voltage rating, the design requirements regarding a system voltage range above 1,000V according to UL may be met. And the thermoplastic material may be rigid enough to satisfy the outer supporting requirements. It is appreciated that the material or material type for the housing 11 and the base 12 in the first embodiment of the present invention may be applied to the junction box according to other embodiments of the present invention.

Referring to FIGS. 2 and 3, the electronic device includes an electrical connection assembly 13 fixed to the base 12 by an over-molding process, the electrical connection assembly 13 being electrically connected with a cable 10 of the photovoltaic module and a conductive bus bar for an external electronic device (for example, a solar current collector (not shown)) respectively. In another embodiment, the electronic device includes two electrical connection assemblies 13 fixed to the base 12 by an over-molding process and a diode 14 connected between the two electrical connection assemblies 13, wherein the two electrical connection assemblies 13 are electrically connected with the cable 10 of the photovoltaic module and the bus bar (not shown) for the external electronic device, respectively. The base 12 may include a first base portion and a second base portion, and the two electrical connection assemblies 13 are fixed to the first and second base portions, respectively.

In another embodiment of the invention, a plurality of positioning pieces 16 protrude from the housing 11 and are arranged along upper and lower rows, and a side portion of the base 12 is adapted to be inserted into a space defined by the plurality of positioning pieces 16 to locate the base 12. Since the base 12 is divided into the first base portion and the second base portion, the positioning of the base in the space defined by the positioning pieces 16 is performed conveniently.

A sealing gel may be used to fill the housing 11 to protect the base 12 and the electronic device (for example, including the electrical connection assembly 13 and the diode 14) from water.

Further, according to the shown embodiment, the junction box 100 may include a cover 15 connected to the housing in a snap-fit way. Specifically, the cover 15 is provided with a plurality of pins 151 having barbs; and the cover 15 is connected to the housing 11 using the pins 151 in a snap-fit way.

Referring to FIG. 3, the housing 11 is provided therein with an annular partition wall 111, and the cover 15 is provided at its inner side with an annular protrusion 152 corresponding to the annular partition wall 111 when assembled with the housing 11 to covers the housing 11. The annular partition wall 111 engages the annular protrusion 152 to seal the housing 11 and cover 15 together, such that the electrical connection assembly 13 and the diode 14 on the base 12 may avoid contact with impurities (i.e. dust and water), and thus the electrical performance of the junction box is improved. In a another embodiment of the invention, an annular groove is provided at an upper part of the annular partition wall 111 so that the annular protrusion 152 is inserted into the annular groove when the cover 15 assembles with the housing 11. Moreover, a sealing gel may be used to further improve sealing between the annular partition wall 111 or the annular groove and the annular protrusion 152.

Still referring to FIG. 3, a gap 114 is formed between the annular partition wall 111 and an inner wall of the housing 11, and the annular partition wall 111 is connected with the inner wall of the housing a plurality of supporting ribs 113, so that the annular partition wall 111 is supported within the housing 11. The bottom of the gap 114 may be closed to receive any impurities (i.e. dust and water) entered through the cover 15. A plurality of through holes 112 may be provided at the outer wall of the housing 11 so that the impurities (i.e. dust and water) in the gap 114 may be discharged, using the through holes 112, outside the housing 11. The bottom of the gap 114 may communicate with the outside. The cover 15 may be connected to the housing 11 by ultrasonic welding for firmer connection.

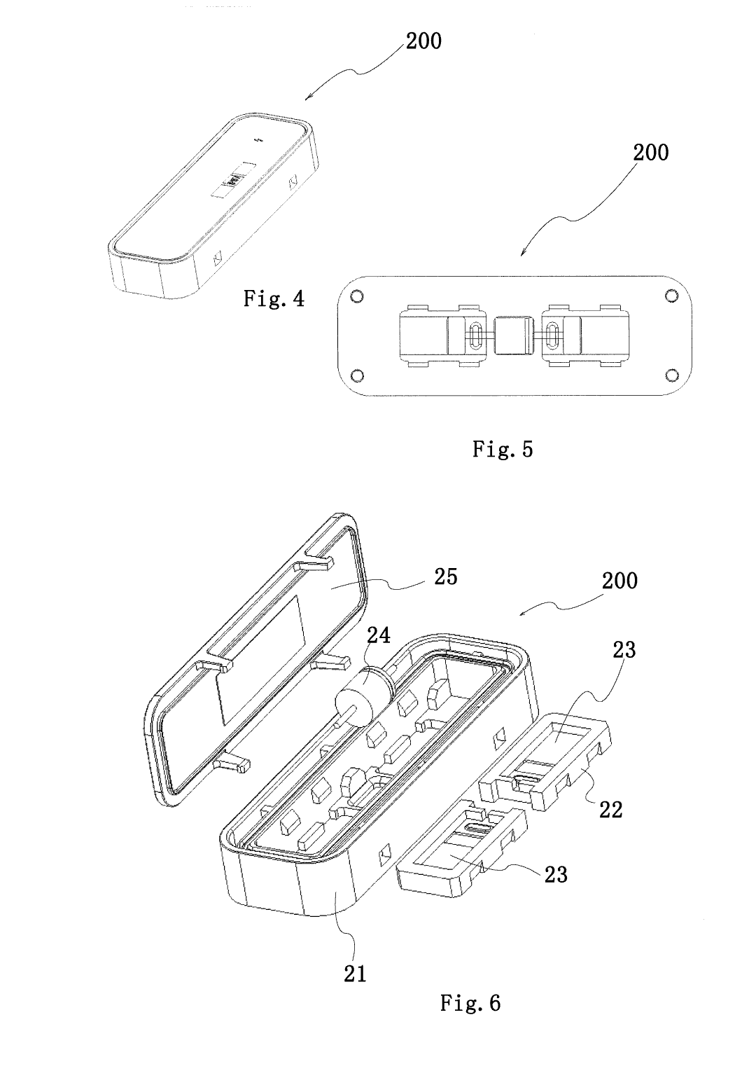

Now with respect to FIGS. 4 through 6, another junction box 200 according to the invention is shown. The junction box 200 differs from the junction box 100 in that two electrical connection assemblies 13 are electrically connected with two bus bars (not shown) for an external electronic device. In addition, the junction box 200 includes a housing 21 made of the thermoplastic material, a base 22 made of the thermosetting material and mounted in the housing 21, two electrical connection assemblies 23 fixed to the base 22 through an over-molding process, a diode 24 connected between the two electrical connection assemblies 23, and a cover 25 for covering the housing 21 in a sealed manner.

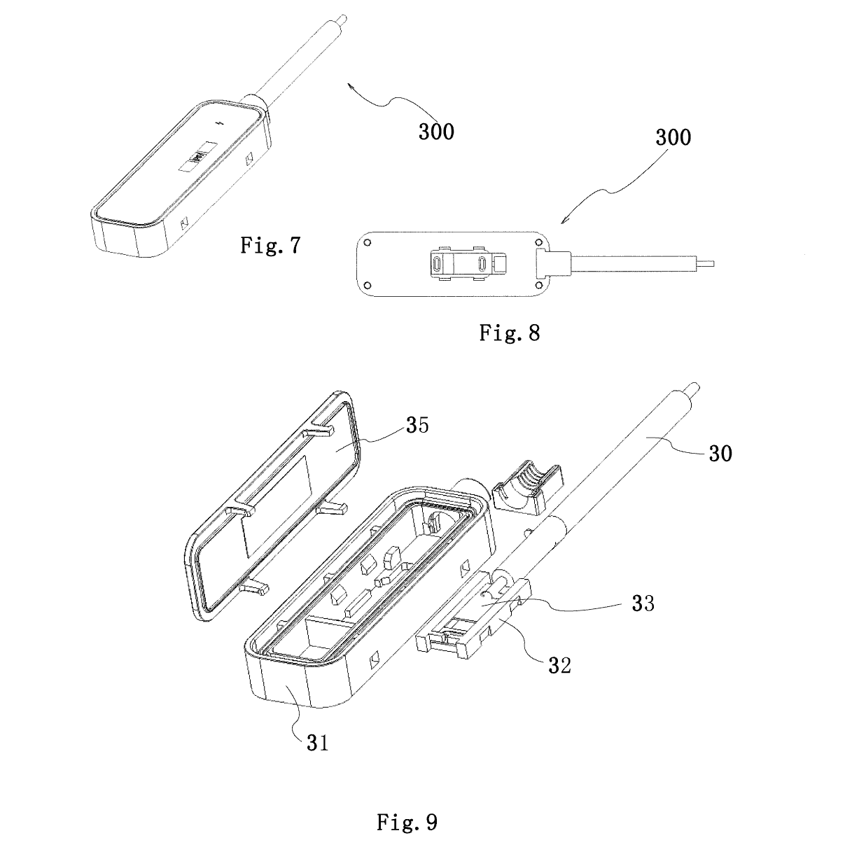

Now with reference to FIGS. 7 through 9, yet another junction box 300 according to the invention is shown. The junction box 300 differs from the junction box 100 in that only one base 32 and one electrical connection assembly 33 are provided, and two ends of the electrical connection assembly 33 are connected to a cable 30 of a photovoltaic module and a bus bar for an external electronic apparatus respectively. In addition, the junction box 300 includes a housing 31 made of the thermoplastic material, a base 32 made of the thermosetting material and mounted in the housing 31, the one electrical connection assembly 33 fixed to the base 32 using an over-molding process, and a cover 35 for covering the housing 31 in a sealed manner.

It is possible that the junction boxes 100, 200, and 330 may be used in combination in a complete solar system.

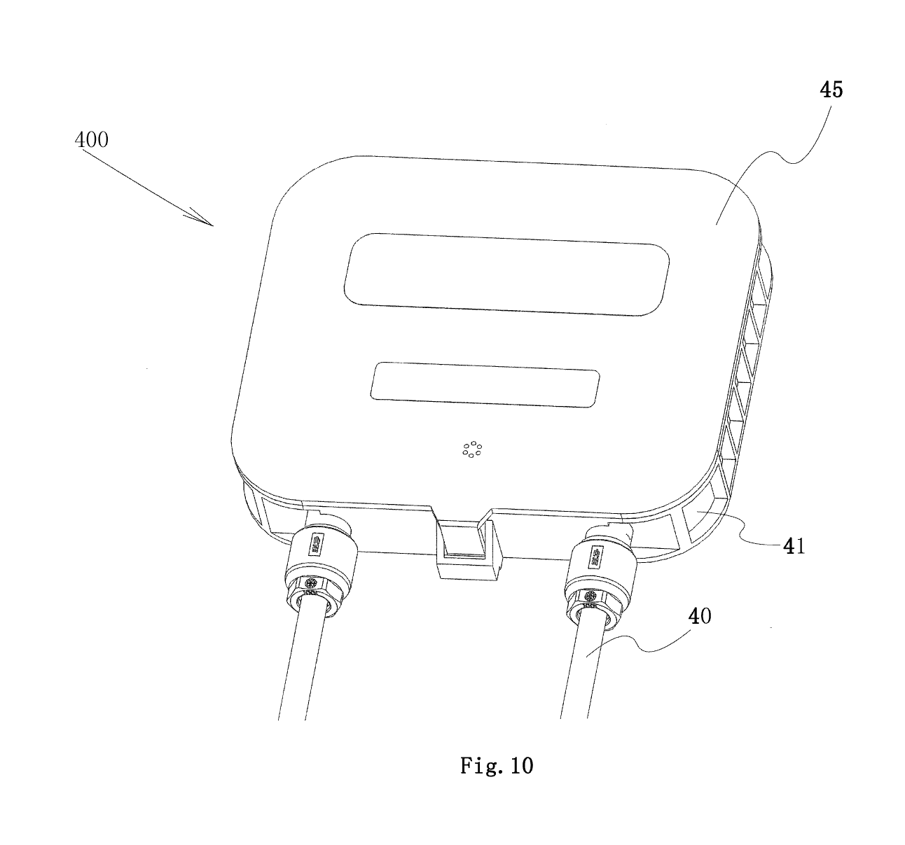

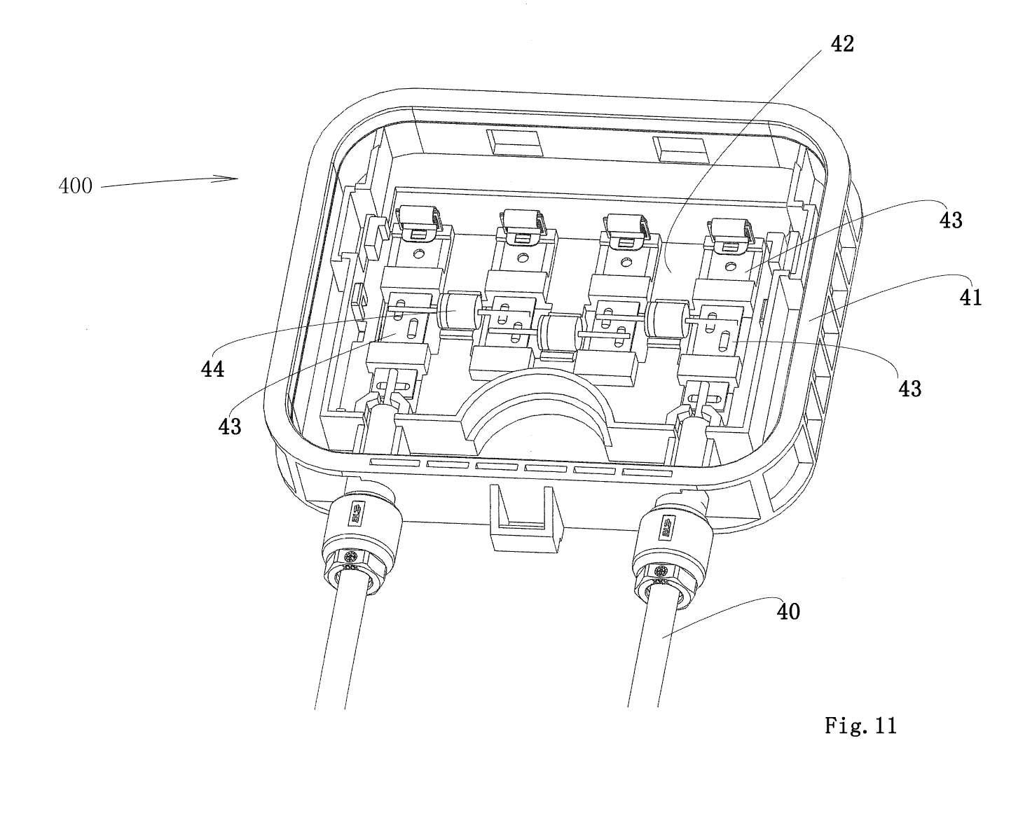

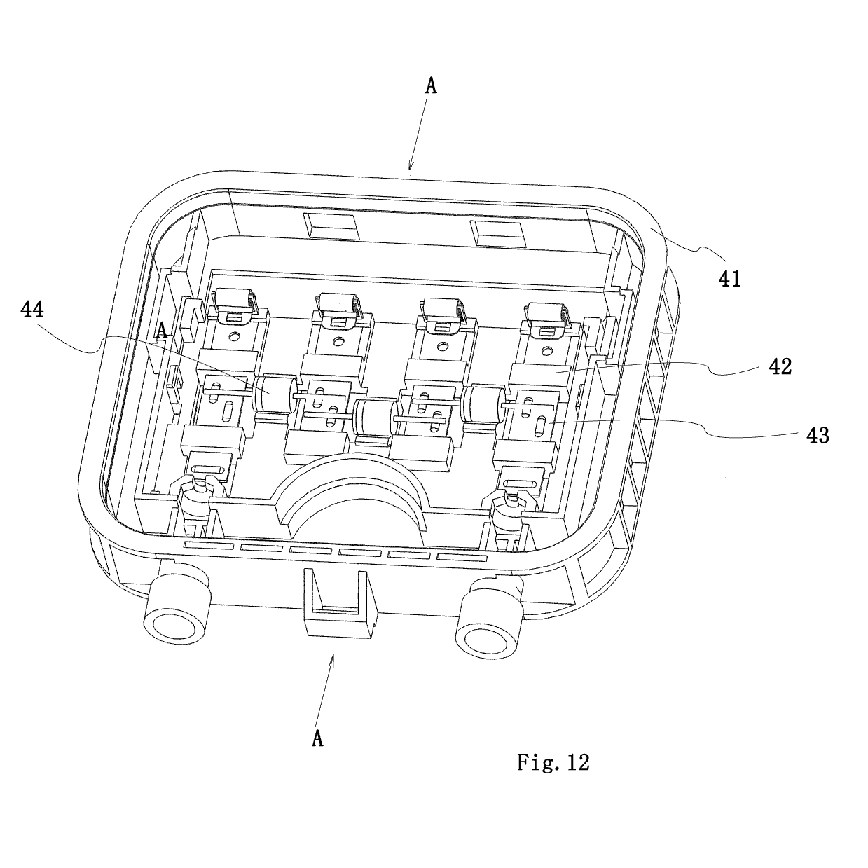

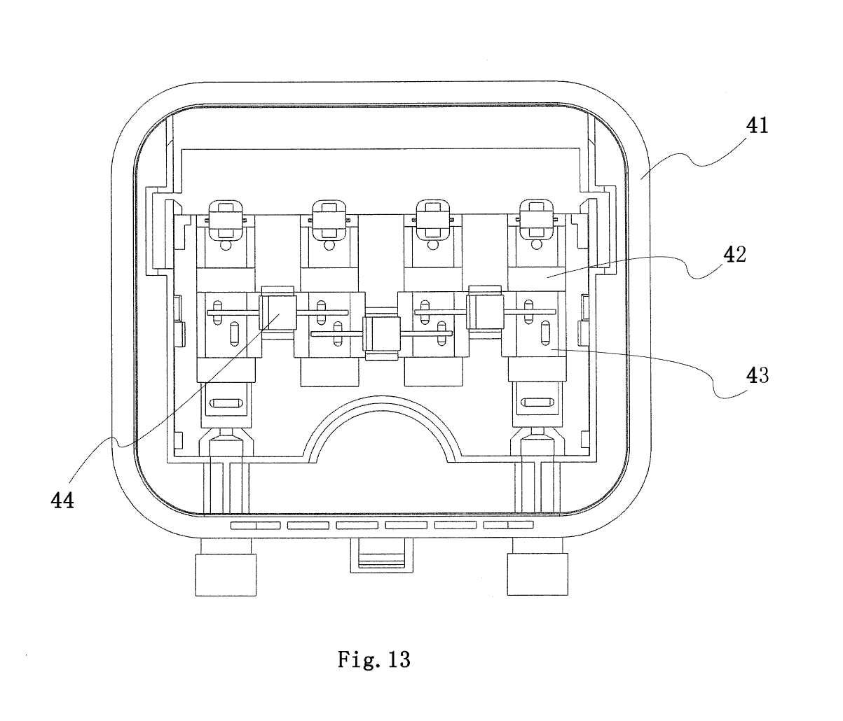

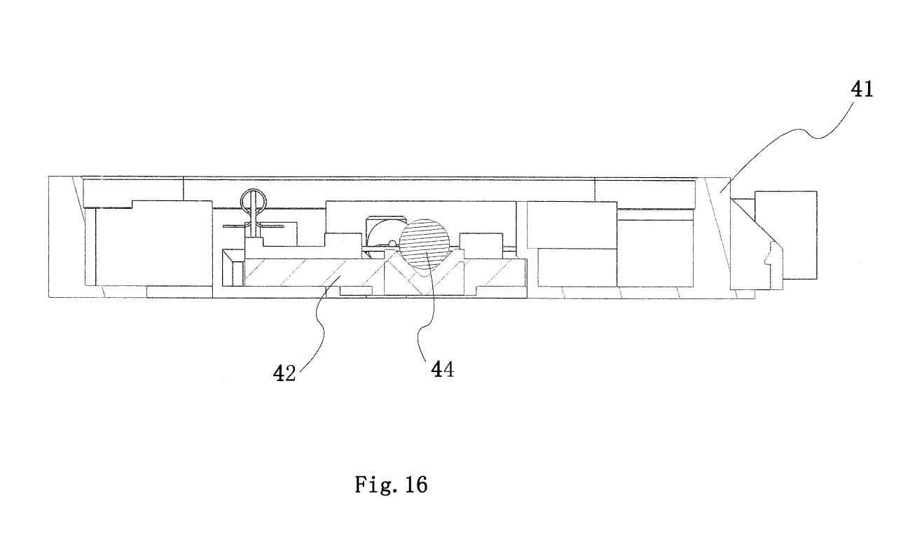

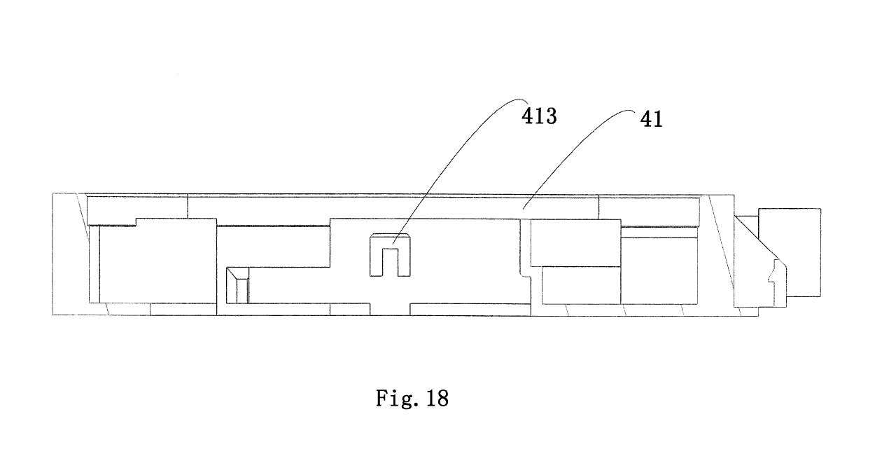

Next, with reference to FIGS. 10 through 18, another junction box 400 according to the invention will be described. The junction box 400 includes a housing 41 having a substantially square or rectangle shape in the embodiment shown, and a base 42 positioned in the housing 41 for mounting at least one electronic device. The housing 41 and the base 42 are separated from each other and are made of different materials. In particular, the housing 41 is made of thermoplastic material, and the base 42 is made of thermosetting material. The specific types of the thermoplastic material and the thermosetting material may be the same as those described in the aforementioned junction boxes 100, 200, and 300 respectively.

As shown, the junction box 400 includes a plurality of electrical connection assemblies 43 provided in parallel to the base 42, and at least one diode 44 each connected between two adjacent ones of the electrical connection assemblies 43. Each electrical connection assembly 43 is adapted to be electrically connected with a bus bar (not shown) for an external electronic device, and two electrical connection assemblies 43 at the outermost side are also connected to two cables 40 of the photovoltaic module respectively. Further, the junction box 400 includes a cover 45 for covering the upper portion of the housing 41 (see FIG. 10).

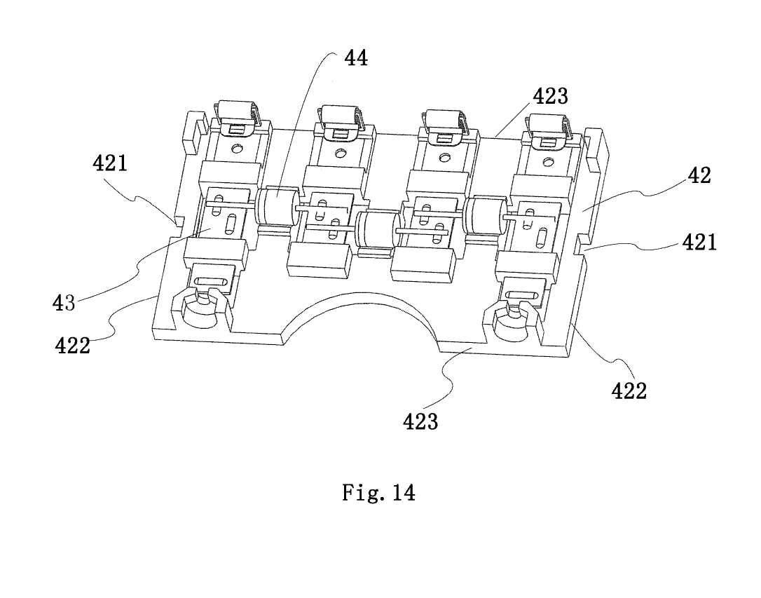

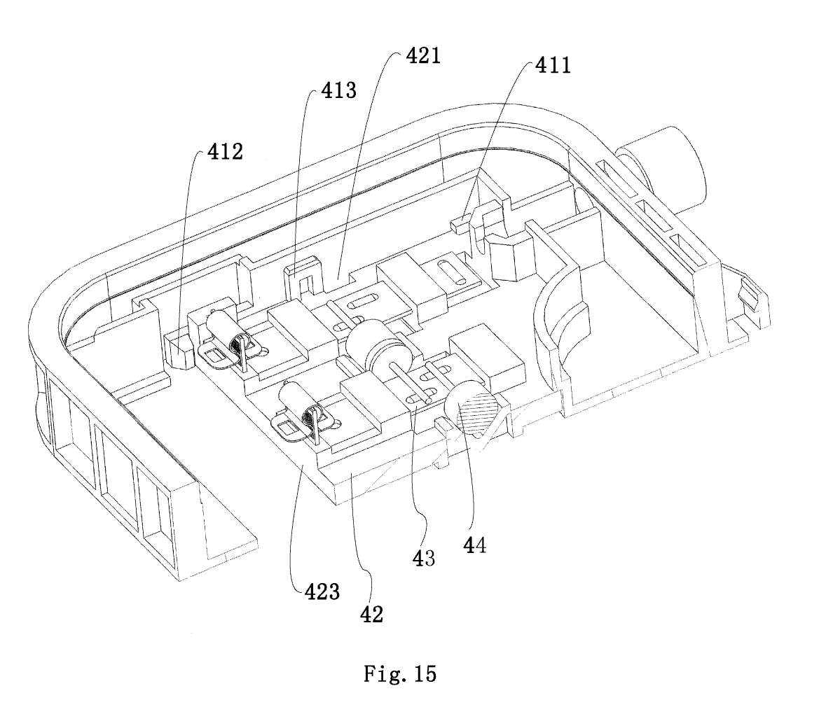

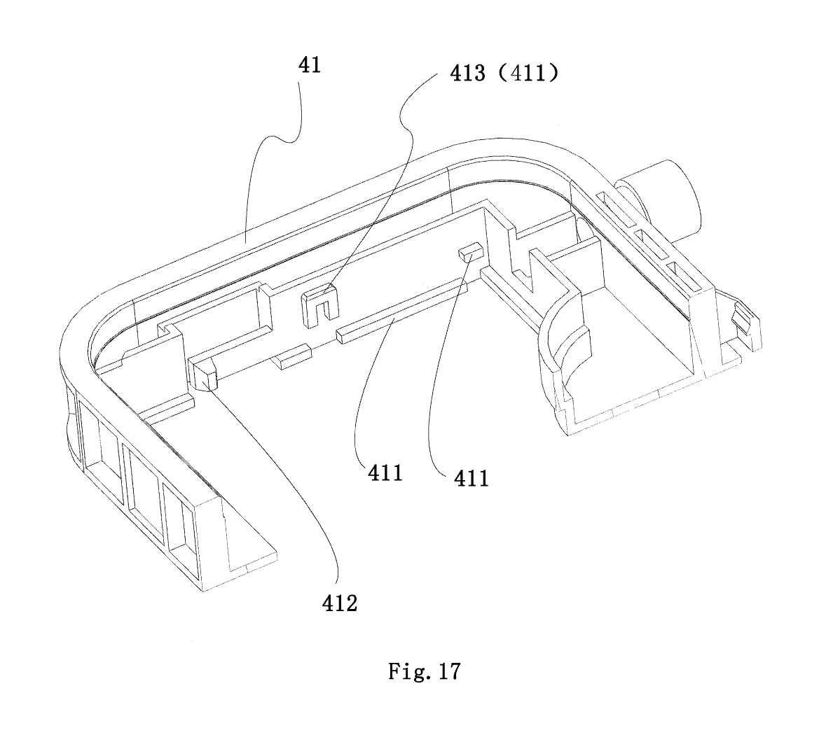

In addition, referring to FIG. 17, the inner wall of the housing 41 includes a plurality of positioning pieces 411 protruding therefrom. Referring to FIGS. 14 and 15, the base 42 includes two opposite first side portions 422 and two opposite second side portions 423, a part of each first side portion 422 is adapted to be inserted into a space defined by the positioning pieces 411 to locate the base 42. Further, referring to FIGS. 14, 15 and 17, at least one pair of notches 421 are formed along the two first side portions 422 respectively; the plurality of positioning pieces 411 include at least one pair of mounting and positioning pieces 413 corresponding, in shape and in position, respectively to the notches 421. Each pair of mounting and positioning pieces 413 extend respectively on two opposite inner walls of the housing 41 in the thickness direction of the housing 41 and are adapted to be slid up and down in the respective notches 421, and the first side portions 422 are adapted to be slid in a left and right direction below the mounting and positioning pieces 413.

With reference to FIGS. 15 and 17, the plurality of positioning pieces 411 further include a pair of elastic positioning pieces 412, provided along the outer side of one of the two second side portions 423 of the base 42 to elastically bias the base 42 along the outer side.

During installation, the electrical connection assemblies 43 and the diode 44 are mounted on the base 42 in the housing 41. After the notches 421 of the base 42 are aligned with the mounting and positioning pieces 413 of the housing 41, the base 42 is pressed downwards so that it is moved to bias the lower positioning pieces 411. While the base 42 is pressed downwards, the inner sides of the elastic positioning pieces 412 are elastically deformed outwards by the pressing of the second side portions 423 of the base 42. Then as shown in FIG. 15, the second side portion 423 along the left side is pushed rightwards, and thus the base 42 is pushed rightwards so that the mounting and positioning piece 413 of the housing 41 is not in alignment with the notch 421 of the base 42 and is above another section of the base 42, excluding the notch 421, so as to prevent the base 42 from moving upwards. In this manner, the elastic positioning piece 412 is returned to its natural state since the inner side thereof is not pressed by the second side portion 423 of the base 42. It should be appreciated that the elastic positioning piece 412 may be returned to a state in which it slightly presses the second side portion 423 of the base 42.

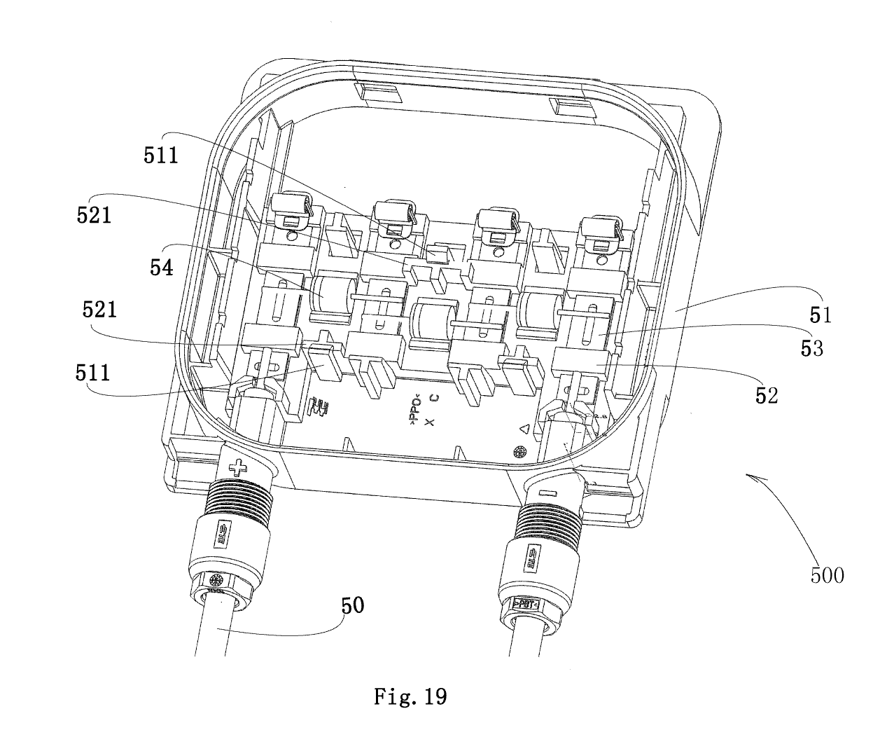

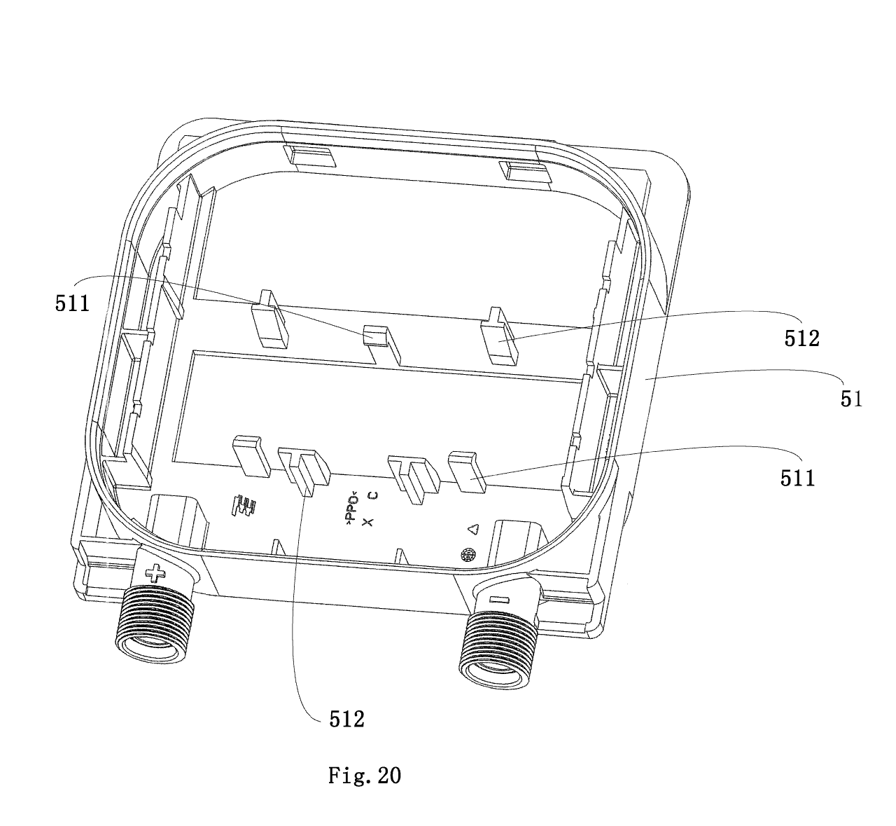

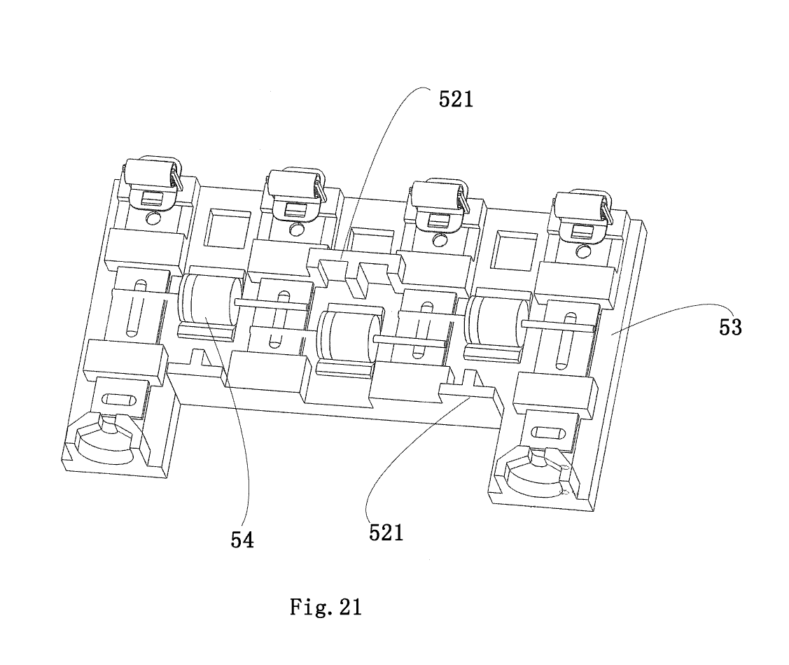

Now with reference to FIGS. 19 through 21, another junction box 500 according to the invention is shown. The junction box 500 is a modified embodiment of the junction box 400 discussed above, and includes a housing 51 having a substantially square or rectangle shape, and a base 52 provided in the housing 51 for mounting at least one electronic device. The housing 51 and the base 52 are separated from each other and are made of different materials. In particular, the housing 51 is made of thermoplastic material, and the base 52 is made of thermosetting material. The specific types of the thermoplastic material and the thermosetting material may be the same as those in the above described embodiments respectively.

In the shown embodiment, the junction box 500 includes a plurality of electrical connection assemblies 53 provided in parallel along the base 52, and at least one diode 54 each connected between two adjacent ones of the electrical connection assemblies 53. Each electrical connection assembly 43 is adapted to be electrically connected with a bus bar (not shown) for an external electronic device, and two electrical connection assemblies 53 along the outermost side are also connected to two cables 50 of the photovoltaic module respectively. Further, the junction box 500 includes a cover (not shown) for covering the upper portion of the housing 51.

In the junction box 500 shown in FIGS. 19 through 21, the bottom of the housing 51 is integrally formed with a plurality of barbs 511 protruding toward an inside of the housing 51, and the base 52 is adapted to be connect with the barbs 511 so as to position the base 52. In addition, a plurality of protrusions 521 are formed integrally on the base 52, and each of the protrusions 521 is engaged with the corresponding barb 511 to locate the base 52. Furthermore, the bottom of the housing 51 is provided with a plurality of positioning pieces 512 protruding therefrom upwards, for locating the side portions of the base 52. When the base 52 is installed in the housing 51, the protrusions 521 are in alignment with the barbs 511 of the housing 51 and then the base 52 is pressed downwards; after the base 52 is in position, the barbs 511 engage with and catch the corresponding protrusions 521, and at the same time the side portions of the base 52 are located by the positioning pieces 512, so that the base 52 is fixed firmly in the housing 51.

Now with reference back to FIG. 3, the housing 11 is provided on the junction box 100 with an adapter 17 for fixing the cable 10 of the photovoltaic module, wherein the adapter 17 is provided therein with recesses 171, and the cable 10 is provided with a clamp 18. At least one tab 181 protruding outwards and radially is formed integrally on the clamp 18, and the at least one tab 181 is adapted to be fit in the corresponding recesses 171. The adapter 17 includes two or more circular members. During assembly, the circular members are provided to enclose the cable 10 to form the whole adapter, wherein the tabs 181 fixed to the cable 10 are inserted into the respective recesses 171 provided in the circular members. The adapter 17 is then connected with a cylinder portion 115, which extends outside the housing 11, and then the adapter 17 is fastened to the cylinder portion 115 by a fastener so that the cable 10 is firmly connected to the junction box 100. Thus, connection failure between the electrical connection assembly 13 and the cable 10 caused by pulling the cable 10 is prevented. It will be appreciated that the adapter for the junction box 100 according to the first embodiment described above may be applied to the junction boxes 300, 400 and 500 according to the invention.

The junction box according to each of the discussed embodiments, in which the housing and the base are separated from each other and are made of different materials (especially, the housing is made of thermoplastic material and the base is made of thermosetting material), meet requirements of a system voltage range of 600-1,000V or greater according to UL. Further, in the junction boxes according to the various discussed embodiments of the invention, the base may be fixed firmly to the housing by using various locating members.

Although several embodiments have been shown and described, it will be appreciated by those skilled in the art that the above embodiments are only for illustration, and various changes or modifications may be made in these embodiments by those skilled in the art without departing from the principles and spirit of the disclosure, the scope of which is defined in the appended claims and their equivalents. In addition, the structures described in the various embodiments may be combined freely if the combined structure is not contrary to the principles of the present invention, thus, more modified junction boxes may be provided for solving the technical problem of the present invention.

As used herein, the word “a” or “an” should be understood as not excluding plural of elements, unless such exclusion is explicitly stated. Moreover, unless explicitly stated to the contrary, the word “comprising” or “having” or “including” may include other elements or steps.

What is claimed is:

1. A junction box for a photovoltaic module, comprising:
a housing made from a first material; and
a base made from a second material, located in the housing, and configured to mount an electronic device.

2. The junction box according to claim 1, wherein the second material has a higher voltage rating than the first material.

3. The junction box according to claim 2, wherein the first material is thermoplastic.

4. The junction box according to claim 3, wherein the second material is a thermoset.

5. The junction box according to claim 4, wherein the electronic device is an electrical connection assembly secured to the base through an over-mold process.

6. The junction box according to claim 5, wherein the electrical connection assembly is electrically connected to a cable of the photovoltaic module and to a bus bar for an external electronic device respectively.

7. The junction box according to claim 4, wherein the electronic device includes a pair of electrical connection assemblies secured to the base through an over-mold process and a diode positioned and connected between the pair of electrical connection assemblies.

8. The junction box according to claim 7, wherein the pair of electrical connection assemblies are electrically connected with a cable of the photovoltaic module and a bus bar for an external electronic device respectively.

9. The junction box according to claim 8, wherein the pair of electrical connection assemblies are electrically connected with two bus bars for two external electronic devices respectively.

10. The junction box according to claim 9, wherein the base includes a first base portion and a second base portion.

11. The junction box according to claim 10, wherein a first electrical connection assembly of the pair of electrical connection assemblies is secured to the first base portion and a second electrical connection assembly of the pair of electrical connection assemblies is secured to the second base portion.

12. The junction box according claim 11, further comprising a plurality of positioning pieces protruding from the housing and arranged into upper and lower rows.

13. The junction box according claim 12, further comprising a base receiving space defined by the plurality of positioning pieces arranged into upper and lowers rows.

14. The junction box according claim 13, wherein a side portion of the base is insertable into the base receiving space to position the base in the housing.

15. The junction box according to claim 14, further comprising a sealing gel within the housing and over the electronic device.

16. The junction box according to claim 15, further comprising a cover connected to the housing.

17. The junction box according to claim 16, wherein the cover connects to the housing in a snap-fit manner.

18. The junction box according to claim 16, further comprising an annular partition wall positioned inside the housing and away from an inner wall of the housing.

19. The junction box according to claim 18, wherein the cover includes an annular protrusion along an inner side thereof.

20. The junction box according to claim 19, wherein the annular protrusion corresponds with the annular partition wall such that the annular partition wall sealingly engages the annular protrusion when the cover is positioned on top of the housing.

21. The junction box according to claim 20, further comprising an annular groove along an upper part of the annular partition wall which receives the annular protrusion when the cover is positioned on top of the housing.

22. The junction box according to claim 20, wherein the annular partition wall is connected with the annular protrusion by the sealing gel.

23. The junction box according to claim 20, further comprising a plurality of supporting ribs positioned in a gap between the annular partition wall and the inner wall.

24. The junction box according to claim 16, wherein the cover is connected to the housing by ultrasonic welding.

25. The junction box according to claim 4, further comprising a cover connected to the housing.

26. The junction box according to claim 25, wherein the cover connects to the housing in a snap-fit manner.

27. The junction box according to claim 25, further comprising an annular partition wall position inside the housing and away from an inner wall of the housing.

28. The junction box according to claim 27, wherein the cover includes an annular protrusion along an inner side thereof.

29. The junction box according to claim 28, wherein the annular protrusion corresponds with the annular partition wall such that the annular partition wall sealingly engages the annular protrusion when the cover is positioned on top of the housing.

30. The junction box according to claim 29, further comprising an annular groove along an upper part of the annular partition wall.

31. The junction box according to claim 30, wherein the annular groove receives the annular protrusion when the cover is positioned on top of the housing.

32. The junction box according to claim 30, further comprising a plurality of supporting ribs positioned in a gap between the annular partition wall and the inner wall.

33. The junction box according to claim 24, wherein the cover is connected to the housing by ultrasonic welding.

34. The junction box according to claim 4, wherein the electronic device includes a pair of electrical connection assemblies provided in parallel to the base.

35. The junction box according to claim 34, wherein the electronic device further includes a diode connected between the pair of electrical connection assemblies.

36. The junction box according to claim 35, wherein each electrical connection assembly of the pair of electrical connection assemblies is connected to a cable connected to the photovoltaic module.

37. The junction box according to claim 34, further comprising a plurality of barbs positioned on a bottom of the housing and protruding towards inside of the housing.

38. The junction box according to claim 37, wherein the base is positioned in the housing and secured by a snap fit connection by the plurality of barbs.

39. The junction box according to claim 38, wherein the base includes a plurality of protrusions that correspond and engage with the plurality of barbs.

40. The junction box according to claim 36, further comprising a plurality of positioning pieces protruding from an inner wall of the housing.

41. The junction box according to claim 40, wherein the base includes a first side portion that is keyed to fit with the plurality of positioning pieces.

42. The junction box according to claim 40, wherein the base includes a pair of first side portions and a pair of second side portions.

43. The junction box according to claim 42, wherein a part of each of the pair of first side portions is adapted to be inserted into a space defined by the plurality of positioning pieces.

44. The junction box according to claim 43, further comprising a pair of notches formed along the pair of first side portions respectively.

45. The junction box according to claim 44, wherein the plurality of positioning pieces include a pair of mounting and positioning pieces corresponding with the pair of notches.

46. The junction box according to claim 45, wherein each of the pair of mounting and positioning pieces extend respectively on two opposite inner walls of the housing and are adapted to be slid within the pair of notches.

47. The junction box according to claim 46, wherein the plurality of positioning pieces further include a pair of elastic positioning pieces along an outer side of one of the pair of second side portions.

48. The junction box according to claim 4, wherein the housing includes an adapter for securing a cable of the photovoltaic module.

49. The junction box according to claim 48, wherein the adapter includes a recess provided therein.

50. The junction box according to claim 49, wherein the cable includes a clamp having a tab protruding outwards and radially from the clamp and being fit in the recess.
